(19) United States
(12) Patent Application Publication
(10) Pub. No.: US 2026/0068672 A1
(43) Pub. Date: Mar. 5, 2026

(54) Doubled-Sided Liquid-Cooling Power Module Mounted with a Plurality of Power Semiconductor Devices

(71) Applicant: DiodSent Green Technology Co., Ltd., Taoyuan (TW)

(72) Inventors: CHI-WEI TSENG, Taoyuan (TW); SIAO-DENG HUANG, Taoyuan (TW); Chien-Chih Tseng, Taoyuan (TW); Nai-Hsi Hu, Taoyuan (TW)

(21) Appl. No.: 18/821,515

(22) Filed: Aug. 30, 2024

(51) Int. Cl. H01L 23/473; H01L 23/00; H01L 23/31; H01L 23/373; H01L 23/538; H01L 25/10

(52) U.S. Cl. CPC H01L 23/473

(57) ABSTRACT

A double-sided liquid-cooling power module mounted with a plurality of power semiconductor devices, including a watertight housing and a power device package, the power device package including a lower ceramic substrate, a power semiconductor device, a copper saddle-shaped upper guide column, an upper ceramic substrate, a shunt support column, and a resin dielectric package, a bottom surface electrode of the power semiconductor device being correspondingly press-bonded with a silver thin film layer, a top surface electrode being press-bonded with an interfacial silver thin film layer; the power semiconductor device is encapsulated by the resin dielectric package; an electrical conduction loop is formed by press-bonding the power semiconductor device to the lower ceramic substrate via the silver thin film layer and press-bonding the copper saddle-shaped upper column to the power semiconductor device via the silver thin film layer; a double-sided heat dissipation effect is achieved with the watertight housing.

### FIELD

The present disclosure relates to a double-sided liquid-cooling power module mounted with a plurality of power semiconductor devices.

### BACKGROUND

With energy transition undergoing across the auto industry in various countries, conventional fossil fuel-powered vehicles have been increasingly replaced by electricity-powered vehicles. Since electric vehicles need to be powered by a high-power motor, the market demand on high-power battery modules grows exponentially and rapidly. Of course, due to whopping energy consumption, a fraction of the energy supplied by the high-power battery module would be inevitably converted to waste heat; in addition, some high-power devices also generate heat when operating in a small space, which contributes to additional temperature rise. Therefore, it is pivotal to control the temperature of heat energy within a certain extent and to enhance stability of operating environment.

A ceramic-based dielectric layer of a circuit substrate exhibits a coefficient of thermal expansion and a high-temperature resistance property close to a semiconductor material, particularly with a thermal conductivity far superior to a complex, multi-layered resin-based substrate. Therefore, the ceramic material is currently generally employed to form the main structure of a substrate for a high-power battery module. However, with increase of the size of the ceramic substrate, irregular warpage and deformation inevitably occur during a sintering process, further leading to an uneven surface of the substrate, so that the circuit components mounted on the circuit substrate would also have some tolerances including skewness, non-levelness, and post-mounting height non-uniformness. In a typical circuit structure, such tolerances are not an issue.

With increase of the current needed for operating of the power devices and the power module, the heating and dissipating issues of the power module become increasingly aggravated, and the conventional single-sided cooling ceramic substrate construction cannot satisfy the need of heat dissipation; therefore, a dual-ceramic-substrate architecture emerges, which achieves heat dissipation via both of the top side and the bottom side of the power device. The heat dissipation construction leveraging two ceramic substrates at the top and bottom sides contributes higher thermal conduction and dissipation efficiency to a high-power battery module.

Currently, a power semiconductor device is soldered on a bonding pad of a ceramic substrate via a nano-silver paste as a wet or soft adhesive material, where the nano-silver paste is reflowed to form a silver connection between the bonding pad of the ceramic substrate and the output-in electrodes of a chip. The nano-silver paste not only offers electrical conduction and thermal conduction properties, but also compensates for connection defect due to size tolerances. However, this nano-silver paste is also doped with other materials, so that after being soldered and cured, its overall electricity conducting efficiency and heat conducting efficiency are both inferior to solid metal connection. If the connection adopts the nano-silver paste solely, the electricity conducting efficiency and the heat conducting efficiency are inevitably restricted, and even a mild increase of resistance would lead to serious rise of thermal resistance under a high-current operating environment, further hindering heat dissipation, which not only affects usage efficiency, but also causes meaningless waste of the limited electrical energy stored in an electric vehicle, causes loss of vehicle range, and even affects the service life of the electric control system. Therefore, it is desirable in the art to enhance heat conducting and electricity conducting efficiencies at top and bottom sides of a power semiconductor device; and considering that warpage of the ceramic substrate likely causes height non-uniformness between a plurality of power semiconductor devices mounted thereon, it is also desirable to avoid height non-uniformness-contributed excessive pressure causing damages to the power semiconductor devices.

### SUMMARY

Hereinafter, the detailed features and advantages of the disclosure will be described through the embodiments, the contents of which suffice for those skilled in the art to understand the technical contents of the disclosure and implement the disclosure based on the contents; and the relevant objectives and advantages of the disclosure may be easily understood by those skilled in the art based on the contents in the description, the claims, and the drawings.

An objective of the disclosure is to provide a double-sided liquid-cooling power module mounted with a plurality of power semiconductor devices, which uses a silver thin film as a bonding structure between the bottom surface electrode of a power semiconductor device and a mounting pad to significantly improve efficiencies of heat conducting and electricity conducting from the bottom side of a power semiconductor, thereby ensuring heat dissipation performance in an operating environment.

Another objective of the disclosure is to provide a double-sided liquid-cooling power module mounted with a plurality of power semiconductor devices, which uses copper saddle-shaped upper guide columns to effectively conduct, from an upper ceramic substrate to an upper thermal conductive housing portion, heat energy generated at the top side of a power semiconductor device.

A further objective of the disclosure is to provide a double-sided liquid-cooling power module mounted with a plurality of power semiconductor devices, where silver paste bonding between shunt support columns and an upper ceramic substrate offers a compensation for warpage of a ceramic substrate and a buffer for reducing risks of damaging a power semiconductor device due to press-bonding applied at the top and bottom sides, thereby increasing yield of module production.

A still further objective of the disclosure is to provide a double-sided liquid-cooling power module mounted with a plurality of power semiconductor devices, where a power semiconductor device conducts heat to a lower thermally conductive housing portion through a lower ceramic substrate, which achieves double-sided heat conduction and dissipation via cooling liquid channels formed in the upper thermally conductive housing portion and in the lower thermally conductive housing portion, respectively, thereby enhancing heat dissipation effect of the overall power semiconductor device.

To achieve the objectives noted supra, the present disclosure provides a double-sided liquid-cooling power module mounted with a plurality of power semiconductor devices, comprising: a watertight housing, the watertight housing comprising an upper thermally conductive housing portion and a lower thermally conductive housing portion, at least one cooling liquid channel being formed in the upper thermally conductive housing portion and in the lower thermally conductive housing portion, respectively; and a plurality of power device packages which are thermally conductively sandwiched between the upper thermally conductive housing portion and the lower thermally conductive housing portion, respectively, each of the power device packages comprising: a lower ceramic substrate having a top side and a bottom side abutting against the lower thermally conductive housing portion; a plurality of metallic pad blocks formed on the top side, and a plurality of power semiconductor mounting pads which are insulative from each other and insulative from the metallic pad blocks, wherein a silver thin film layer is press-bonded on each of the power semiconductor mounting pads, respectively; a plurality of power semiconductor devices with a count corresponding to a count of the power semiconductor mounting pads, each of the power semiconductor devices having a bottom surface electrode, two top surface electrodes which are spaced from each other, and at least one top surface gate insulated from the top surface electrodes; wherein the bottom surface electrode of each of the power semiconductor devices is correspondingly press-bonding connected to the silver thin film layer, respectively, and an interfacial silver thin film layer is press-bonded on each of the top surface electrodes, respectively; a plurality of copper saddle-shaped upper guide columns with a count corresponding to a count of the power semiconductor devices, each of the copper saddle-shaped upper guide columns having two feet which are press-bonded on the interfacial silver thin film, respectively; an upper ceramic substrate having a thermally conductive top surface and a bottom surface, a plurality of bottom pads press-bonded to the copper saddle-shaped upper guide columns being formed beneath the bottom surface; a plurality of shunt support columns, one end of each of the shunt support columns being soldered on a corresponding one of the metallic pad blocks, another end opposite to the one end being soldered to a corresponding one of the bottom pads via a silver paste; and a resin dielectric package completely encapsulating the power semiconductor devices, the copper saddle-shaped upper guide columns, and the shunt support columns.

The conductive connection via the press-bonded silver thin film offers optimum electricity conducting and heat conducting properties between the power semiconductor devices and the power semiconductor mounting pads on the lower ceramic substrate: the silver thin film is superior to a conventional nano-silver paste in terms of electrical conduction coefficient and thermal conduction coefficient; particularly, the silver thin film can achieve a thickness of only about 20 μm with a uniform height, so that even if a warpage-induced height difference is unneglectable for a large-footprint ceramic substrate, the warpage-induced height difference would be insignificant due to a relatively small footprint of a power semiconductor device, so that the bonding positions can be well fit; in addition to the tight bonding provided by the press-bonding process, no micro-voids would be generated at the bonding interface, ensuring that the bonding interface is secure and desired. This structural design enables the heat generated by the power semiconductor devices, which are main heat sources, to be efficiently conducted downward to the lower ceramic substrate.

Secondly, the top surface electrodes above the power semiconductor devices are also conductively connected to the copper saddle-shaped upper guide columns by press-bonding a silver thin film, so that the heat generated by the power semiconductor devices may also efficiently conducted to the guide columns above and transferred upward towards the upper ceramic substrate. Since the lower ceramic substrate and the upper ceramic substrate abut against the lower thermally conductive housing portion and the upper thermally conductive housing portion, respectively, the heat generated by the power semiconductor devices may be conducted out in a double-sided manner; particularly, due to the short lower-side conductive path, reliable sealing of the bonding interface, and the low thermal resistance of the conductive path, heat dissipation performance is effectively improved over conventional technologies.

Furthermore, due to the large overall footprints of the lower and upper ceramic substrates, the warpage-induced height difference cannot be neglected; if the existing silver paste is entirely replaced by the silver thin film, an undesired structural stress would be caused at any unexpected protruding position, so that if the stressed position is accidentally a power semiconductor device, microcracks would occur to cause damages; a worse situation is that the defect would arise unpredictably, so that if a potentially defective power semiconductor device passes quality inspection and mounted on a vehicle, the adverse effect would be hard to measure. Therefore, the present disclosure reserves silver paste bonding between the plurality of shunt support columns disposed at the outer side and the bottom pads of the upper ceramic substrate, so that even if the thermal conduction effect is somewhat sacrificed, a good mechanical buffer can be offered; the soft property of the silver paste before curing can offer a good buffer effect when the upper ceramic substrate presses downward; in addition, the soft nature can compensate for a larger range of size errors; meanwhile, arrangement of the plurality of shunt support columns can effectively limit the downward-pressing height of the upper ceramic substrate, further preventing excessively pressing against the copper saddle-shaped upper guide columns causing damages to the power semiconductor devices.

### BRIEF DESCRIPTION OF THE DRAWINGS

FIG. 1 is a schematic structural side view of a power device package assembled in a watertight housing according to the disclosure.

FIG. 2 is a schematic layout diagram of cooling liquid channels according to the disclosure.

FIG. 3 is a stereoscopic diagram of a power device package.

FIG. 4 is a stereoscopic exploded view of the power device package.

FIG. 5 is a stereoscopic schematic diagram of a bottom side of an upper ceramic substrate.

FIG. 6 is a stereoscopic diagram of a layout structure of metallic pad blocks and power semiconductor mounting pads in a lower ceramic substrate.

FIG. 7 is a structural stereoscopic diagram of a power semiconductor mounting pad bonded with a silver thin film layer.

FIG. 8 is a structural stereoscopic view of a power semiconductor device press-bonding connected to a silver thin film layer.

FIG. 9 is a stereoscopic schematic view of press-bonding copper saddle-shaped upper guide columns and shunt support columns.

### DETAILED DESCRIPTION OF EMBODIMENTS

Hereinafter, the embodiments of the disclosure will be illustrated through specific implementations; and those skilled in the art may easily understand other advantages and effects of the disclosure based on the contents described herein.

The structures, scales, and sizes as illustrated in the drawings of the disclosure are only intended for facilitating those skilled in the art to read and understand the contents of the description, not for limiting conditions of implementing the disclosure, so that they do not have substantive technical meanings; any structural modifications, scale changes, or size adjustments shall fall within the scope of the technical contents disclosed herein without affecting the effects produced or objectives achieved by the disclosure. Meanwhile, terms such as “one,” “two,” and “above” referred to herein are also intended only for easing the description, not for limiting the protection scope of the disclosure, and modifications or adjustments to the relative relationships shall also be deemed as falling within the protection scope of the disclosure without substantively changing the technical contents.

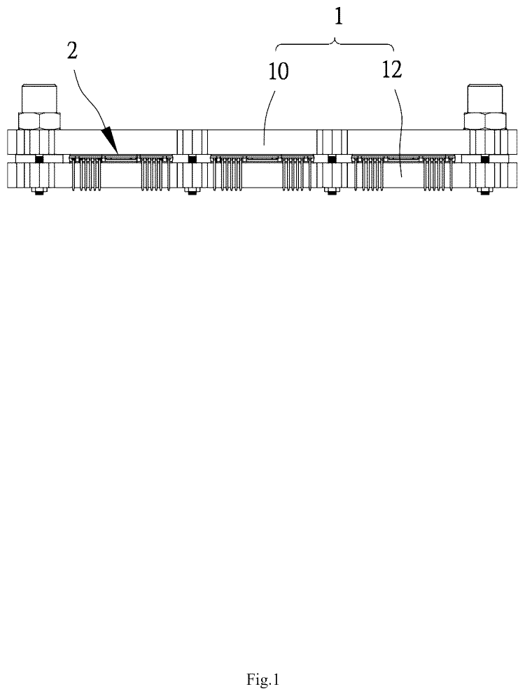

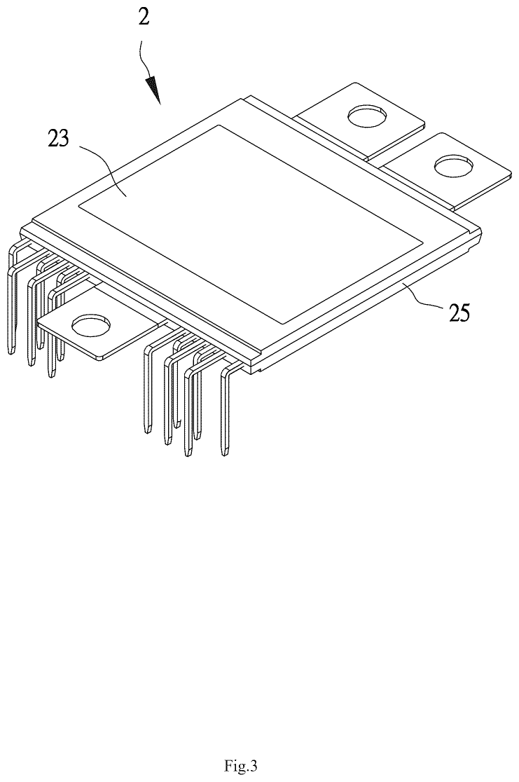

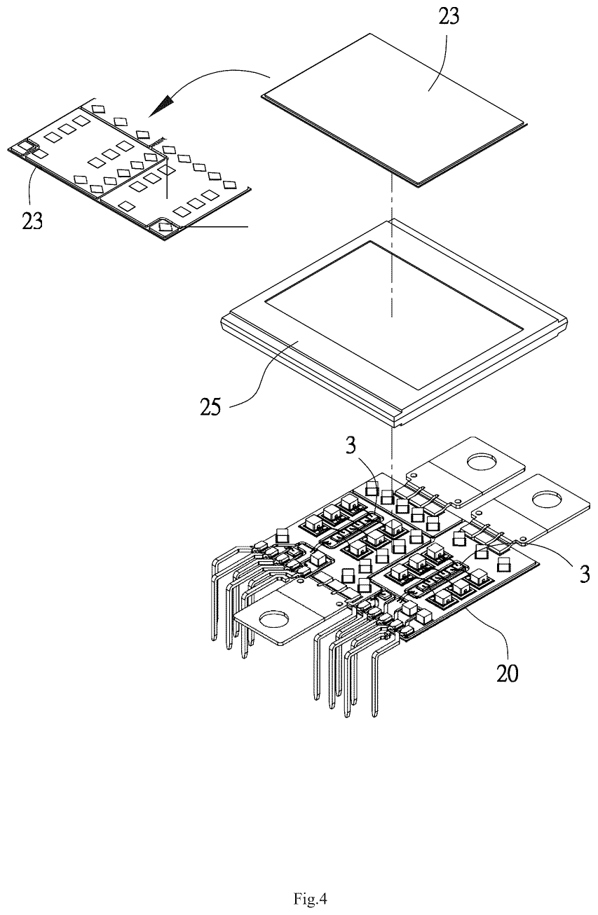

FIGS. 1 to 4 illustrate a schematic structural side view of a power device package assembled in a watertight housing, a schematic layout diagram of cooling liquid channels, a stereoscopic diagram of a power device package, and a stereoscopic exploded view of the power device package according to the disclosure. The present disclosure provides a double-sided liquid-cooling power module mounted with a plurality of power semiconductor devices, comprising: a watertight housing 1 and a power device package 2, the watertight housing 1 comprising an upper thermally conductive housing portion 10 and a lower thermally conductive housing portion 12, at least one cooling liquid channel 12 being formed in the upper thermally conductive housing portion 10 and in the lower thermally conductive housing portion 12, respectively, the power device package 2 being thermally conductively sandwiched between the upper thermally conductive housing portion 10 and the lower thermally conductive housing portion 12, the power device package 2 comprising a lower ceramic substrate 20, a power semiconductor device 21, a copper saddle-shaped upper guide column 22, an upper ceramic substrate 23, a shunt support column 24, and a resin dielectric package 25.

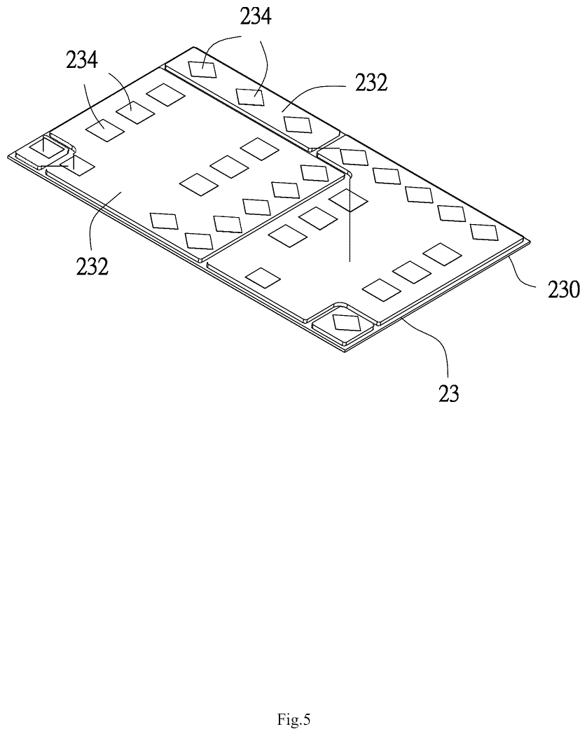

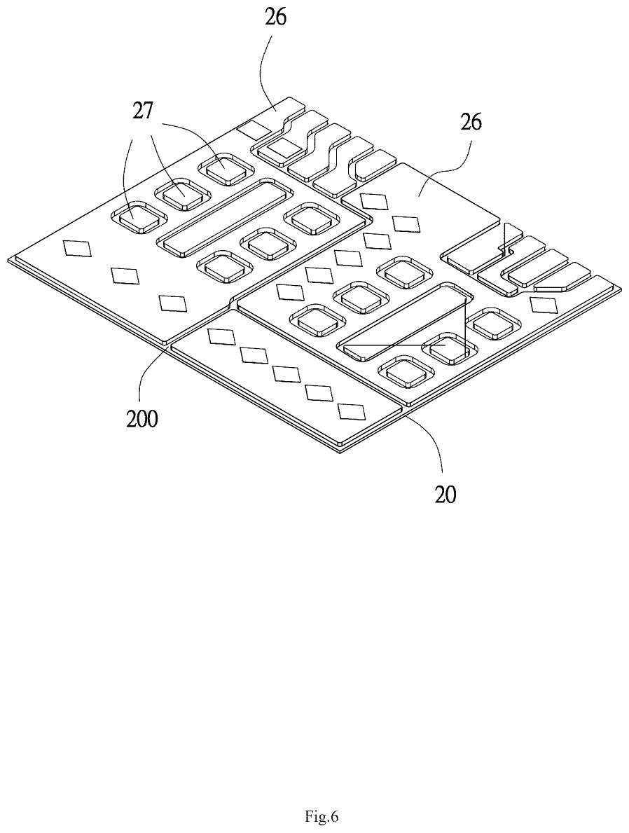

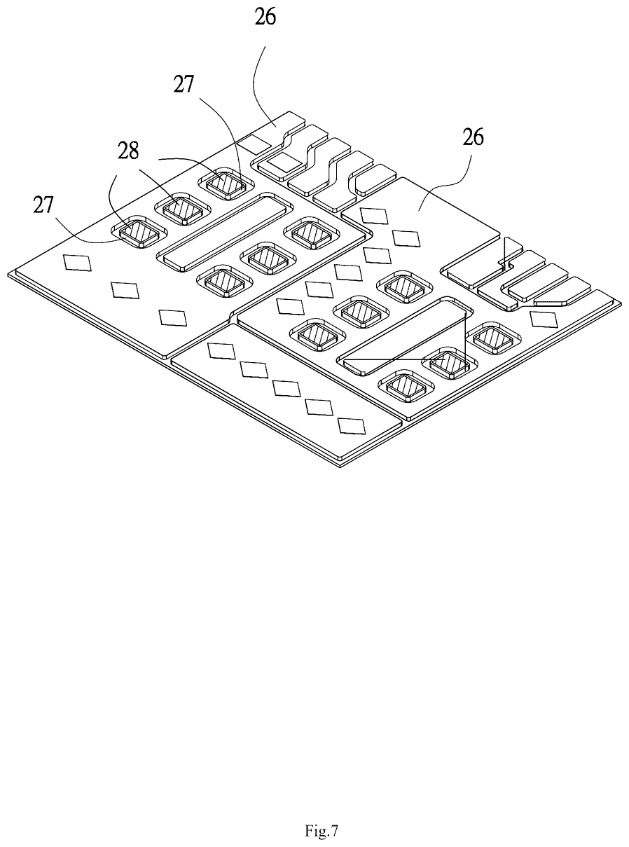

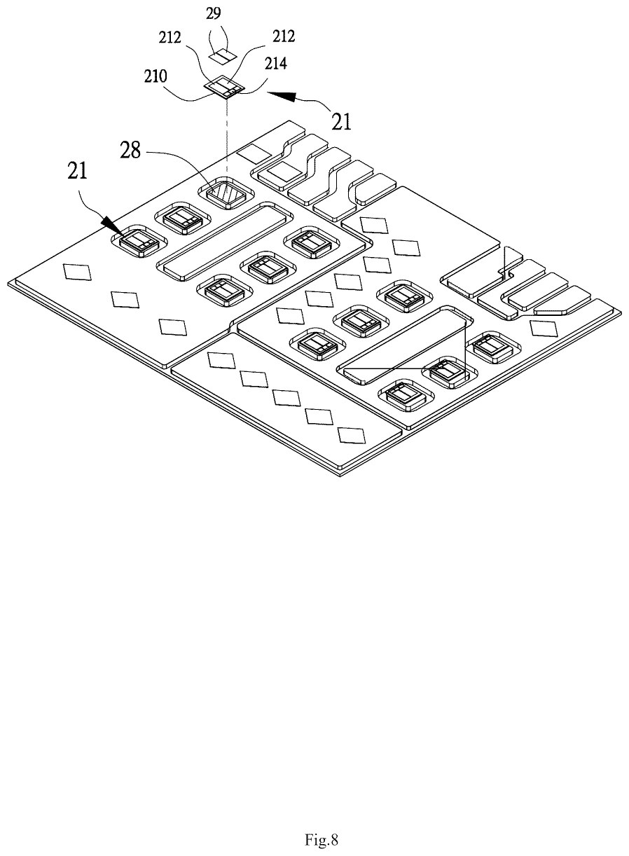

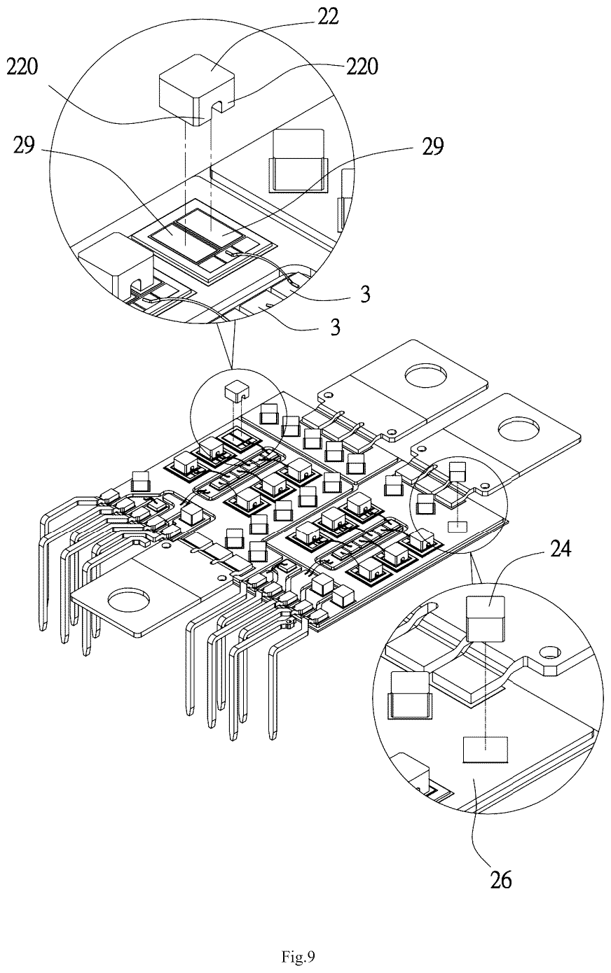

Also referring to FIG. 5 illustrating a stereoscopic schematic diagram of a bottom side of an upper ceramic substrate, FIG. 6 illustrating a stereoscopic diagram of a layout structure of metallic pad blocks and power semiconductor mounting pads in a lower ceramic substrate, FIG. 7 illustrating a structural stereoscopic diagram of a power semiconductor mounting pad bonded with a silver thin film layer, FIG. 8 illustrating a structural stereoscopic view of a power semiconductor device press-bonding connected to a silver thin film layer, and FIG. 9 illustrating a stereoscopic schematic view of bonding copper saddle-shaped upper guide columns and shunt support columns, it can be clearly seen that in the power device package 2, the upper ceramic substrate 23 has a thermally conductive top surface 230 and a bottom surface 232, a plurality of bottom pads 234 being formed beneath the bottom surface 232.

The lower ceramic substrate 20 has a top side 200 and a bottom side 202 abutting against the lower thermally conductive housing portion 12, a plurality of metallic pad blocks 26 and power device mounting pads 27 being formed on the top side 200, respective metallic pad blocks 26 being insulative from the power semiconductor mounting pads 27, a silver thin film layer 28 being press-bonded on each of the power semiconductor mounting pads 27, respectively, while each silver thin film layer 28 being configured for press-bonding connecting a corresponding power semiconductor device 21; therefore, a count of the power semiconductor mounting pads 27 corresponds to a count of the power semiconductor devices 21.

Each of the power semiconductor devices 27 has a bottom surface electrode 210, two top surface electrodes 212 spaced from each other, and at least one top surface gate 214 insulated from the top surface electrodes 212; the bottom surface electrode 210 of each of the power semiconductor devices 21 being correspondingly press-bonding connected to the silver thin film layer 28, respectively, and an interfacial silver thin film layer 29 being press-bonded on each top surface electrode 212. As noted supra, even if the lower ceramic substrate might have a certain proportion of noticeable warpage from an overall large-extent perspective during mass production, the warpage-induced height difference can be neglectable due to the smaller size of any of the power semiconductor devices; therefore, the press-bonding manner would cause no damages to the power semiconductor devices, and the silver thin film layers can also ensure that the bottom surface electrodes of the power semiconductor devices are all securely, firmly, and closely attached onto the power semiconductor mounting pads. Furthermore, heat from the bottom of the power semiconductor device may be well conducted out to the lower ceramic substrate thereunder so as to be carried away by the cooling liquid. Moreover, since the overall thickness of the silver thin film layer and the power semiconductor mounting pad is very thin, the temperature gradient between the power semiconductor device and the lower thermally conductive housing portion thereunder is very large, and according to a heat conduction equation, the thermal conduction efficiency would be particularly excellent.

Each power semiconductor device 21 noted supra is correspondingly provided with a copper saddle-shaped upper guide column 22, the copper saddle-shaped upper guide column 22 having two feet 220, each foot 220 being press-bonded on the interfacial silver thin film layer 29, the opposite side of the copper saddle-shaped upper guide column 22 being press-bonded to the bottom pad 234 of the upper ceramic substrate 23. In this way, the top surface electrode above the power semiconductor device may be well connected to the copper saddle-shaped upper guide column via the interfacial silver thin film layer. Since the height of the copper saddle-shaped upper guide column is nearly 2 mm, the temperature gradient at the upper side is smaller than the height difference-induced temperature gradient at the lower side, so that the upper side is only a secondary thermally conductive path; therefore, a silver thin film or a silver paste may be selected between the copper saddle-shaped upper guide column and the bottom pad of the upper ceramic substrate dependent on situations.

For the plurality of shunt support columns 24, one end of each shunt support column 24 is soldered to any position of the metallic pad block 26, an opposite end thereof is soldered to a corresponding one of the bottom pads 234 of the upper ceramic substrate via the silver paste. Since the shunt support column 24 is made of a fully metallic material, it is more stress resistant than a semiconductor device; in addition, the silver paste is relatively soft before curing, so that it may play a role of buffering; particularly, since the shunt support column 24 is not disposed in the main thermally conductive path of the power semiconductor device, even if a few micro-voids are formed during the soldering process to generate some thermal resistance, it would not cause a serious heating issue to the overall module; therefore, the shunt support column may not only play a role of electrical conduction as designed, but also may play a role of supporting the downward-pressing upper ceramic substrate, thereby preventing the power semiconductor device from being excessively stressed and damaged; moreover, the silver-paste bonding here may also provide buffering to compensate for the warpage-induced height difference between the overall upper ceramic substrate and the lower ceramic substrate. Finally, the resin dielectric package 25 is used to fully encapsulate the power semiconductor devices 21, the copper saddle-shaped upper guide columns 22, and the shunt support columns 24.

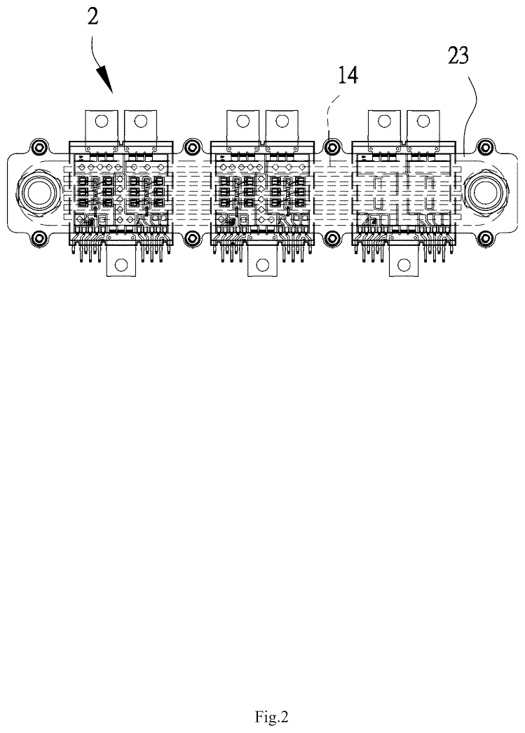

In view of the above, to form a complete electrical conduction loop, a power semiconductor device 21 in the power device package 2 is mounted to the lower ceramic substrate 20 by press-bonding the bottom surface electrode 210 to the corresponding silver thin film layer 28, the top surface electrode 212 is press-bonded with the interfacial silver thin film layer 29, the copper saddle-shaped upper guide column 22 is press-bonded to the upper ceramic substrate 23, and the top surface gate 214 is conductively connected to a drive 3, respective power semiconductor devices 21 in each power device package 2 being driven by the drive 3, respectively. For example, FIG. 2 illustrates 3 sets of power device packages 2; each power device package 2 is partitioned into a plurality of power semiconductor devices 21 in the left half and a plurality of power semiconductor devices 21 in the right half, while the respective power semiconductor devices 21 in the left half and the respective power semiconductor devices 21 in the right half of each power device package 2 are driven alternately, or none of them is driven; when the 3 sets of power device packages 2 operate as packages, the driving manner is such that the power semiconductor devices 21 in left or right half portions of two of the 3 sets are selected to be driven, while the remaining 1 set of power semiconductor devices 21 are not driven. Simply put, the 3 sets of power device packages 2 are partitioned into 6 half portions of power semiconductor devices 21, while only 2 half portions thereof are driven to operate.

A complete electrical conduction loop of a driven power device package 2 is formed in such a manner that the electrical energy is conducted to the lower ceramic substrate 20 via an electrical conduction terminal, then conducted to the power semiconductor device 21 via the power semiconductor mounting pad 27 and the silver thin film layer 28, then conducted to the copper saddle-shaped upper guide column 22 via the interfacial silver thin film layer 29 on the power semiconductor device 22, and finally outputted via a planar terminal after being conducted to the shunt support column 24 via the upper ceramic substrate 23.

Furthermore, in order to dissipate the heat generated during electricity conduction of each power semiconductor device 21 in the power device package 2 via the watertight housing 1 in a double-sided heat conducting manner, the power device package 2 needs to be mounted to abut between the upper thermally conductive housing portion 10 and the lower thermally conductive housing portion 12 both of which have cooling liquid channels 14. The plurality of power semiconductor devices 21 in the power device package 2 are mounted, via the silver thin film layers 28, on the lower ceramic substrate 20 having the power semiconductor mounting pads 27, whereby the heat is conducted through the cooling liquid channels 14 on the lower ceramic substrate 20; the mutually spaced top surface electrodes 212 on the power semiconductor device 21 are respectively press-bonded with an interfacial silver thin film layer 29 to thereby press-bond with respective feet 220 of the copper saddle-shaped upper guide column 22, while the opposite side of the copper saddle-shaped upper guide column 22 is press-bonded to the bottom pad 234 of the upper ceramic substrate 23, so that heat can be conducted via the copper saddle-shaped upper guide column 22 to the upper ceramic substrate 23 and dissipated through the cooling liquid channels 14. In addition, the silver thin film layer 28 and the interfacial silver thin film layer 29 are both formed by dry silver; the high-temperature fusion-bonding can effectively prevent air voids and provide a good levelled contact, whereby the overall heat conduction effect can be enhanced.

In addition, since the top and bottom sides of the power semiconductor device 21 are respectively bonded with an interfacial silver thin film layer 29 and a silver thin film layer 28 which are both of a dry electrically conductive material, to prevent the copper saddle-shaped upper column 22 from excessively pressing the power semiconductor device 21 causing damages thereto, a plurality of shunt support columns 24 are provided, which can effectively limit the downward-pressed height of the upper ceramic substrate. Moreover, respective opposite ends of the shunt support columns 24 are press-bonded to the bottom pads 234 of the upper ceramic substrate 23 via the silver paste; due to the soft nature of the silver paste, the downward-pressing upper ceramic substrate 23 is well buffered, further preventing the copper saddle-shaped upper guide columns from excessively pressing downward causing damages to the power semiconductor devices.

The implementations described supra exemplarily illustrate the principle and effects of the disclosure, not intended for limiting the disclosure. Those skilled in the art may modify the implementations without departing from the spirits and scope of the disclosure. Therefore, the extent of protection of the disclosure shall be defined by the appending claims.

I/We claim:

1. A double-sided liquid-cooling power module mounted with a plurality of power semiconductor devices, comprising:
a watertight housing, the watertight housing comprising an upper thermally conductive housing portion and a lower thermally conductive housing portion, at least one cooling liquid channel being formed in the upper thermally conductive housing portion and in the lower thermally conductive housing portion, respectively; and
a plurality of power device packages which are thermally conductively sandwiched between the upper thermally conductive housing portion and the lower thermally conductive housing portion, respectively, each of the power device packages comprising:
a lower ceramic substrate having a top side and a bottom side abutting against the lower thermally conductive housing portion;
a plurality of metallic pad blocks formed on the top side, and a plurality of power semiconductor mounting pads which are insulative from each other and insulative from the metallic pad blocks, wherein a silver thin film layer is press-bonded on each of the power semiconductor mounting pads, respectively;
a plurality of power semiconductor devices with a count corresponding to a count of the power semiconductor mounting pads, each of the power semiconductor devices having a bottom surface electrode, two top surface electrodes which are spaced from each other, and at least one top surface gate insulated from the top surface electrodes; wherein the bottom surface electrode of each of the power semiconductor devices is correspondingly press-bonding connected to the silver thin film layer, respectively, and an interfacial silver thin film layer is press-bonded on each of the top surface electrodes, respectively;
a plurality of copper saddle-shaped upper guide columns with a count corresponding to a count of the power semiconductor devices, each of the copper saddle-shaped upper guide columns having two feet which are press-bonded on the interfacial silver thin film, respectively;
an upper ceramic substrate having a thermally conductive top surface and a bottom surface, a plurality of bottom pads press-bonded to the copper saddle-shaped upper guide columns being formed beneath the bottom surface;
a plurality of shunt support columns, one end of each of the shunt support columns being soldered on a corresponding one of the metallic pad blocks, another end opposite to the one end being soldered to a corresponding one of the bottom pads via a silver paste; and
a resin dielectric package completely encapsulating the power semiconductor devices, the copper saddle-shaped upper guide columns, and the shunt support columns.

2. The double-sided liquid-cooling power module mounted with a plurality of power semiconductor devices according to claim 1, wherein a silver thin film is press-bonded between each of the shunt support columns and a corresponding one of the metallic pad blocks, respectively.
